(19) United States
(12) Patent Application Publication
(10) Pub. No.: US 2010/0085720 A1
(43) Pub. Date: Apr. 8, 2010

(54) JOINED STRUCTURE, METHOD FOR PRODUCING THE SAME, AND ANISOTROPIC CONDUCTIVE FILM USED FOR THE SAME

(75) Inventor: Toshiyuki Shudo, Kanuma-shi (JP)

Correspondence Address: BUCHANAN, INGERSOLL & ROONEY PC, POST OFFICE BOX 1404, ALEXANDRIA, VA, 22313-1404, US

(73) Assignee: Sony Chemical & Information Device Corporation, Tokyo (JP)

(21) Appl. No.: 12/633,993

(22) Filed: Dec. 9, 2009

Related U.S. Application Data
(63) Continuation of application No. PCT/JP2009/056268, filed on Mar. 27, 2009.

(30) Foreign Application Priority Data
Apr. 18, 2008 (JP) 2008-109171

(51) Int. Cl. H05K 1/11; H01R 43/00

(52) U.S. Cl. 361/792; 29/825

(57) ABSTRACT

A joined structure of the present invention including a first substrate having a wiring thereon, any one of a second substrate and an electronic part, and an anisotropic conductive film containing conductive particles, wherein the first substrate and any one of the second substrate and the electronic part are electrically joined via the anisotropic conductive film, and wherein the conductive particles pressure-bonded to the wiring of the first substrate protrude from both edges of the wiring in a width direction, and an interval of the wiring is 3.5 times or more larger than an average particle diameter of the conductive particles which are not pressure-bonded to the wiring.

### CROSS-REFERENCE TO RELATED APPLICATION

This is a continuation of Application No. PCT/JP2009/056268, filed on Mar. 27, 2009.

### BACKGROUND OF THE INVENTION

1. Field of the Invention

The present invention relates to a joined structure in which an electronic part of an IC chip or a liquid crystal panel (LCD panel) of a liquid crystal display (LCD) and a substrate, or substrates are electrically connected, a method for producing the joined structure, and an anisotropic conductive film used for the joined structure.

2. Description of the Related Art

Anisotropic conductive adhesion films (ACF: Anisotropic Conductive Film) have conventionally been used as a means for connecting an electronic part and a circuit substrate. The anisotropic conductive adhesion film is used for adhering and electrically connecting between various terminals, for example a case for connecting a flexible print substrate (FPC) or a terminal of an IC chip with an ITO (Indium Tin Oxide) electrode formed on a glass substrate of LCD panel.

Commonly used anisotropic conductive adhesion film is a film in which conductive particles are dispersed in an epoxy resin insulating adhesive layer. For example, terminals of an IC chip and an ITO electrode are electrically connected by crushing the conductive particles between the terminals of the IC chip and the ITO electrode of a glass substrate.

The recent trends for miniaturized and high performance electronic devices lead to joint terminals of fine pitch, and as a result, the joint area of the terminal is reduced. Even though the joint area is reduced, high particle capturing ability and conductive reliability are still required.

Here, a particle diameter of the conductive particles contained in the anisotropic conductive adhesive film is generally smaller than the width of the joint terminal such as bump, wiring and the like (for example, Japanese Patent Application Laid-Open (JP-A) No. 2006-339323) (FIG. 6). Therefore, there have been the studies and attempts for securing high particle capturing ability, obtaining excellent conductive reliability and preventing short circuit, in the case where the joint terminal such as bump, wiring and the like is fine-pitched, by making the particle diameter of the conductive fine particles smaller so as to obtain a state where the conductive fine particles are averagely dispersed on the joint terminal (FIG. 7).

However, when the particle diameter of the conductive fine particles is made smaller according to a fine-pitched joint terminal, pressure upon joining (pressure-bonding) needs to be increased to sufficiently crush the particles. In the case where a material having low strength such as glass is used as a material for the electronic part or the substrate, the electronic part or the substrate may be cracked upon joining (pressure-bonding). Moreover, as the electronic part or the substrate is getting thinner recently, it is desired to join (pressure-bond) the electronic part and the circuit substrate at lower pressure.

### BRIEF SUMMARY OF THE INVENTION

The present invention is aimed to solve the above conventional problems, and to achieve the following object. Namely, an object of the present invention is to provide a joined structure which can attain the sufficiently crushed state of particles, so that excellent conductive reliability can be obtained and occurrence of short circuit can be suppressed, even when the fine-pitch substrate and the electronic part or the like are joined, a method for producing the joined structure, and an anisotropic conductive film used for the joined structure.

A means for solving the problems is as follows.
<1> A joined structure including: a first substrate having a wiring thereon; any one of a second substrate and an electronic part; and an anisotropic conductive film containing conductive particles, wherein the first substrate and any one of the second substrate and the electronic part are electrically joined via the anisotropic conductive film, and wherein the conductive particles pressure-bonded to the wiring of the first substrate protrude from both edges of the wiring in a width direction, and an interval of the wiring is 3.5 times or more larger than an average particle diameter of the conductive particles which are not pressure-bonded to the wiring.

In the joined structure, the conductive particles having a large average particle diameter are used, so that the conductive particles pressure-bonded to the wiring of the first substrate protrude from both edges of the wiring in a width direction. Thus, the particles can be sufficiently crushed so as to obtain excellent conductive reliability, even when the fine-pitch substrate and the electronic part or the like are joined. Moreover, as the interval of the wiring (space width) of the first substrate is 3.5 times or more larger than the average particle diameter of the conductive particles which are not pressure-bonded to the wiring, the interval of the wiring (space width) is sufficiently wide, in which the conductive particles are connected so as to prevent short circuit between the wirings in one substrate.
<2> A joined structure including: a first substrate having a wiring thereon; any one of a second substrate and an electronic part; and an anisotropic conductive film containing conductive particles, wherein the first substrate and any one of the second substrate and the electronic part are electrically joined via the anisotropic conductive film, and wherein an average particle diameter of the conductive particles which are not pressure-bonded to the wiring of the first substrate is larger than a width of the wiring, and an interval of the wiring is 3.5 times or more larger than the average particle diameter of the conductive particles which are not pressure-bonded to the wiring.

In the joined structure, an average particle diameter of the conductive particles which are not pressure-bonded to the wiring of the first substrate is larger than the width of the wiring. Thus, the particles can be sufficiently crushed so as to obtain excellent conductive reliability, even when the fine-pitch substrate and the electronic part or the like are joined. Moreover, as the interval of the wiring (space width) of the first substrate is 3.5 times or more larger than the average particle diameter of the conductive particles which are not pressure-bonded to the wiring, the interval of the wiring (space width) is sufficiently wide, in which the conductive particles are connected so as to prevent short circuit between the wirings in one substrate.
<3> The joined structure according to any one of <1> and <2>, wherein the anisotropic conductive film includes a binder resin and the binder resin contains at least one selected from an epoxy resin and an acrylic resin.
<4> A method for producing the joined structure according to any one of <1> to <3>, including: forming the anisotropic conductive film containing conductive particles on a surface to be processed; and joining the first substrate and any one of the second substrate and the electronic part via the anisotropic conductive film.
<5> An anisotropic conductive film including conductive particles, wherein the anisotropic conductive film is used for the joined structure according to any one of <1> to <3>.

The present invention can solve the above conventional problems, and provide a joined structure which can attain the sufficiently crushed state of particles so as to obtain excellent conductive reliability and can prevent occurrence of short circuit, even when the fine-pitch substrate and the electronic part or the like are joined, a method for producing the joined structure, and an anisotropic conductive film used for the joined structure.

### BRIEF DESCRIPTION OF THE DRAWINGS

FIG. 1 is a schematic explanatory view showing (substantially spherical) conductive particles which are pressure-bonded on a wiring of a first substrate of a joined structure of the present invention.

FIG. 2 is a schematic explanatory view showing a (indeterminate) conductive particle which is pressure-bonded on the wiring of the first substrate of the joined structure of the present invention.

FIG. 3 is a schematic explanatory view showing conductive particles (secondary particle (aggregated particles)) which are pressure-bonded on the wiring of the first substrate of the joined structure of the present invention.

FIG. 4 is a schematic explanatory view showing a line width (wiring width) L and a space width (wiring interval) S of the first substrate.

FIG. 5 is a schematic explanatory view showing a structure of the wiring of the first substrate.

FIG. 6 is a schematic explanatory view showing a conventional joined structure.

FIG. 7 is a schematic explanatory view showing conductive particles pressure-bonded on the wiring of the first substrate in the conventional joined structure.

### DETAILED DESCRIPTION OF THE INVENTION

### (Joined Structure)

The joined structure of the present invention includes a first substrate having a wiring thereon, any of a second substrate and an electronic part, and an anisotropic conductive film containing conductive particles, wherein the first substrate and any of the second substrate and the electronic part are electrically joined via the anisotropic conductive film. That is, the conductive particles are crushed between a terminal (wiring) of the first substrate and a terminal of the electronic part, or between the terminal (wiring) of first substrate and a terminal (wiring) of the second substrate, so as to achieve conduction between the terminals.

In the joined structure, the conductive particles pressure-bonded to the wiring of the first substrate (i.e., the conductive particles crushed between the terminal of the first substrate and the terminal of the electronic part, or the terminal of the first substrate and the terminal of the second substrate) protrude from both edges of the wiring in a width direction, and an interval of the wiring is 3.5 times or more larger than an average particle diameter of the conductive particles which are not pressure-bonded to the wiring (the conductive particles which are not crushed between the terminal of the first substrate and the terminal of the electronic part, or between the terminal of the first substrate and the terminal of the second substrate). The interval of the wiring is more preferably 4 times or more larger than the average particle diameter of the conductive particles which are not pressure-bonded to the wiring.

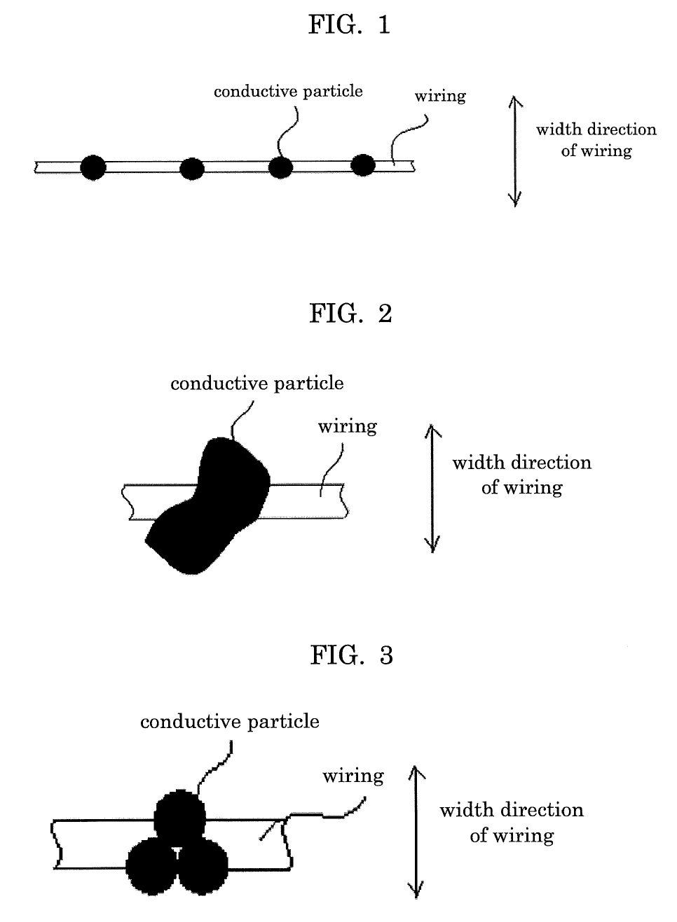

Here, “the conductive particles pressure-bonded to the wiring of the first substrate” may be a substantially spherical shape (FIG. 1) or an indeterminate shape (FIG. 2).

“Protrude from both edges of the wiring in a width direction” includes not only the case where one conductive particle (a primary particle) protrudes from both edges of the wiring in a width direction as shown in FIGS. 1 and 2, but also the case where a plurality of conductive particles (secondary particle (aggregated particles)) protrude from both edges of the wiring in a width direction as shown in FIG. 3.

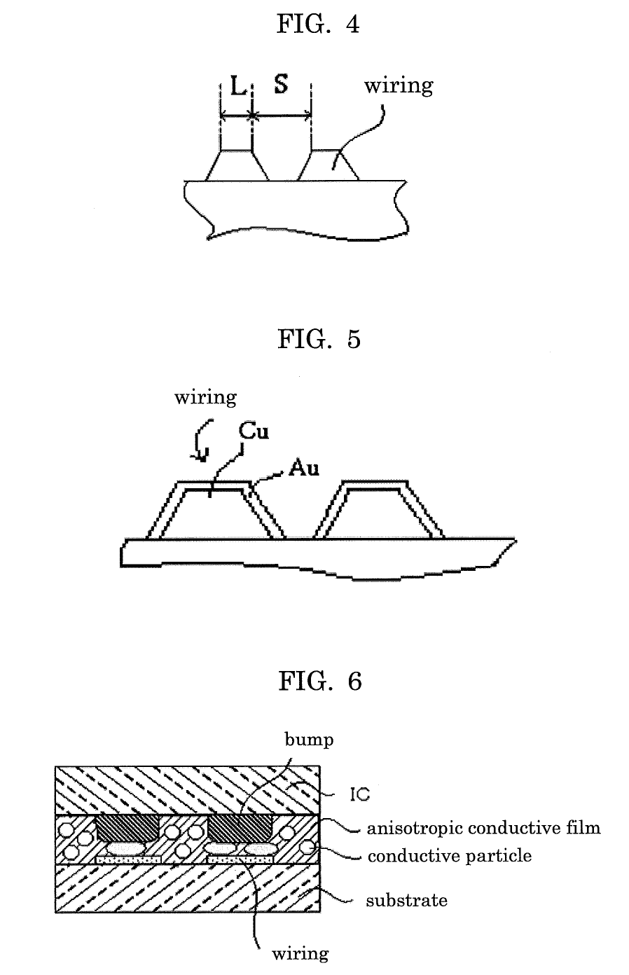

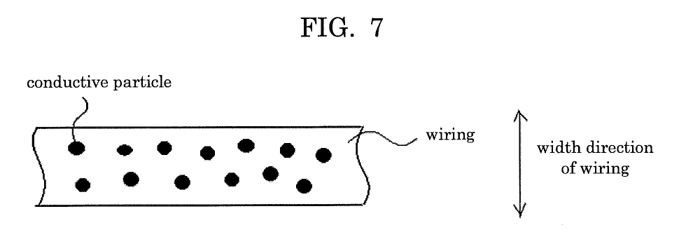

“The interval of the wiring” indicates a space width (wiring interval) S in FIG. 4 and an average value of 10 space width values measured by a microscope. In FIG. 4, L denotes a line width (wiring width), which is an average value of 10 line width values measured by the microscope.

“An average particle diameter of the conductive particles which are not pressure-bonded to the wiring” indicates an average value of the 10 measured values obtained in such a manner that 10 conductive particles which are not pressure-bonded to the wiring (i.e., which are not deformed by joining (pressure-bonding)) are observed by a microscope (STM-UM, manufactured by Olympus Corporation), and each of the particle diameters of the observed conductive particles is measured, and then the average value of the 10 measured valued is obtained.

Here, it is essential that the space width (wiring interval) S of the first substrate is 3.5 times or more larger, more preferably 4 times or more larger than the line width (wiring width) L of the first substrate, and that an average particle diameter of the conductive particles (which includes the secondary particle (aggregated particles) as well as the primary particle) pressure-bonded to the wiring of the first substrate is larger than the line width (wiring width) L.

The joined structure of the present invention can attain the sufficiently crushed state of the particles so as to obtain excellent conductive reliability and to prevent occurrence of short circuit, even when the fine-pitch substrate and the electronic part or the like are joined, as the conductive particles pressure-bonded to the wiring of the first substrate protrude from both edges of the wiring in a width direction, and an interval of the wiring (space width S) is 3.5 times or more larger, preferably 4 times or more larger than an average particle diameter of conductive particles which are not pressure-bonded to the wiring.

### —Substrate—

The substrate is suitably selected depending on the intended purpose without any restriction. Examples thereof include ITO glass substrates, flexible substrates, rigid substrates, and flexible print substrates.

### —Electronic Part—

The electronic part is suitably selected depending on the intended purpose without any restriction. Examples thereof include IC chips such as an IC chip for controlling a liquid crystal display in a flat panel display (FPD) or liquid crystal panels.

### —Anisotropic Conductive Film—

The anisotropic conductive film includes at least conductive particles, and preferably further includes a binder resin, and further includes suitably selected other components as necessary. The anisotropic conductive film preferably has a thickness of 10 μm to 50 μm.

—Conductive Particle—The conductive particles are suitably selected from those having the same structure as the one used in the conventional anisotropic conductive adhesive, without any restriction. Examples thereof include: metal particles of pewter, nickel or the like; resin, glass or ceramic particles coated with metal (nickel, gold, aluminum, copper, or the like) plating; and the aforementioned particles coated with an insulating material. By using these conductive particles, the irregularities in the smoothness of the terminals and substrate wiring to be joined are absorbed, and the process margin can be maintained at the time of the production. In addition, the conduction can be maintained even when the connecting point is detached by pressure, and thus high reliability can be attained.

Among these conductive particles, metal-coated resin particles, e.g. nickel-gold-plated resin particles, are preferable, and insulating particles which are formed by coating the metal-coated resin particles with an insulating resin are more preferable as these particles are capable of preventing a short circuit caused as a result that the conductive particles go into between terminals.

### —Binder Resin—

The binder resin is preferably at least one selected from an epoxy resin and an acrylic resin.

The epoxy resin is suitably selected depending on the purpose without any restriction. Examples of the epoxy resin include bisphenol A epoxy resin, bisphenol F epoxy resin, and novolak epoxy resin. These may be used singly or in combination.

The acrylic resin is suitably selected depending on the purpose without any restriction. Examples thereof include methyl acrylate, ethyl acrylate, isopropyl acrylate, isobutyl acrylate, epoxy acrylate, ethylene glycol diacrylate, diethylene glycol diacrylate, trimethylol propane triacrylate, dimethyloltricyclodecane diacrylate, tetramethylene glycol tetraacrylate, 2-hydroxy-1,3-diacryloxypropane, 2,2-bis[4-(acryloxymethoxy)phenyl]propane, 2,2-bis[4-(acryloxyethoxy)phenyl]propane, dicyclopentenyl acrylate, tricyclodecanyl acrylate, tris(acryloxyethyl)isocyanurate, and urethane acrylate. These may be used singly or in combination.

Examples thereof also include the above examples wherein the acrylate is changed to methacrylate. These may be used singly or in combination.

### —Other Component—

The other components are suitably selected from additives known in the art depending on the intended purpose without any restriction, provided that they do not adversely affect the effect obtainable by the present invention. Examples thereof include a filler, a softener, an accelerator, an antioxidant, a colorant, a flame retardant, and a silane coupling agent.

The amount of the other components is suitably selected depending on the amount of the conductive particles and the binder resin without any restriction.

### (Meth of Producing Joined Structure)

The method for producing the joined structure of the present invention includes at least an anisotropic conductive film forming step and a joining step, and further includes suitably selected other steps as necessary.

### <Anisotropic Conductive Film Forming Step>

The anisotropic conductive film forming step is a step of forming an anisotropic conductive film containing conductive particles on a surface to be treated. Examples of the anisotropic conductive film forming step include a method of applying a coating liquid containing a resin composition in which the conductive particles are dispersed in the binder resin onto a surface to be treated (coating method), and a method of spraying onto a surface to be treated conductive particles, which are ejected using one spraying unit, and then to which electrostatic potential is applied by an electrostatic potential applying unit, and resin particles, which are ejected using the other spraying unit, at the same time (spraying method).

### <Joining Step>

The joining step is a step of joining the first substrate and any one, of the second substrate and the electronic part via the anisotropic conductive film.

The joining step is suitably selected depending on the intended purpose without any restriction, provided that the first substrate and any one of the second substrate and the electronic part are pressure-bonded via the anisotropic conductive film. For example, the first substrate and any one of the second substrate and the electronic part are pressure-bonded via the anisotropic conductive film at 100° C. to 300° C. and 0.1 MPa to 200 MPa for 1 second to 50 seconds.

### Examples

Hereinafter, Examples of the present invention will be explained, but these examples shall not be construed as to limit the scope of the present invention in any way.

### Example 1

### —Production of Anisotropic Conductive Film (ACF1)—

Twenty parts by mass of a liquid bisphenol epoxy resin (“E828” manufactured by Japan Epoxy Resins Co., Ltd.) as a binder resin, 20 parts by mass of a phenoxy resin “PKHH” manufactured by InChem Corp., 20 parts by mass of an amine-based latent curing agent “HX3941” manufactured by Asahi Kasei Chemicals Corporation, and Ni—Au plated resin particles as conductive particles (manufactured by Nippon Chemical Industrial Co., LTD., average particle diameter: 10 μm, hereinafter referred to as “gold particles”), which were adjusted so that 1,000 number/mm² of the Ni—Au plated resin particles were contained in a film to be formed, were mixed, and toluene as a solution was added in the mixture, so as to prepare a coating liquid containing a resin composition in which conductive particles were dispersed in the binder resin.

The average particle diameter of the gold particles is an average value of 10 values measured by a microscope.

As an object (a surface to be treated) to be coated with the coating liquid containing the resin composition in which the conductive particles were dispersed in the binder resin, a film formed of polyethylene terephthalate (PET), i.e. a PET layer, was prepared.

Next, the prepared coating liquid was applied onto the film (PET layer) by a bar coater under a predetermined coating conditions. As a result, on a surface of the PET layer, an epoxy resin coated film (an anisotropic conductive film) was formed, in which the gold particles were dispersed in the epoxy resin.

The obtained epoxy resin coated film was heated in an oven at 70° C. for 5 minutes to evaporate toluene, thereby obtaining an epoxy resin film containing 1,000 number/mm² of the gold particles (in a thickness of 18 μm).

### —Production of Joined Structure—

Using the produced anisotropic conductive film (ACF1), a joined structure of a flexible print substrate (FPC) A described below and an ITO glass was produced.

### [Flexible Print Substrate (FPC) A]

Material: polyimide; external dimension: 46 mm×36 mm, thickness: 0.020 mm

Type of wiring: a gold plated copper wiring (FIG. 5), a line width (wiring width) L (FIG. 4): 8 μm (an average value of 10 values measured by a microscope), a space width (wiring interval) S (FIG. 4): 42 μm (an average value of 10 values measured by the microscope), a wiring height: 12 μm

### [ITO Glass]

Thickness: 0.7 mm

ITO (10 Ω/square)

The flexible print substrate (FPC) A was laid over the ITO glass so that the wiring of the flexible print substrate (FPC) A and the conductive pattern of the ITO glass faced each other via the anisotropic conductive film, and they pressure-bonded under the conditions of heating at 180° C. at 1 MPa or 3 MPa in a pressure-bonded width of 2 mm for 20 seconds, thereby obtaining a joined structure.

With respect to joined structures of Example 1 (pressure-bonding conditions: 1 MPa) and Comparative Example 1 (pressure-bonding conditions: 1 MPa), short circuit and conductive resistance were measured by the following method. The results are shown in Table 1.

### <Continuity Short Circuit Test>

Next, a conductive resistance value (Ω) of each joined structure was measured by the four-terminal method and the number of occurrence of short circuit between two terminals was evaluated. The results are shown in Table 1. It is preferred that the conductive resistance value (Ω) immediately after pressure-bonding be 5Ω or less and that no short circuit occur.

### Comparative Example 1

An anisotropic conductive film was produced, and then a joined structure was produced in the same manner as in Example 1, except that Ni—Au plated resin particles having an average particle diameter of 5 μm were used instead of the Ni—Au plated resin particles having an average particle diameter of 10 μm as the conductive particles in the production of the anisotropic conductive film of Example 1. The anisotropic conductive film produced in Comparative Example 1 was defined as ACF2.

### Comparative Example 2

An anisotropic conductive film was produced, and then a joined structure was produced in the same manner as in Example 1, except that a flexible print substrate (FPC) B was used instead of the flexible print substrate (FPC) A in the production of the anisotropic conductive film of Example 1.

Material: polyimide; external dimension: 43 mm×36 mm, thickness: 0.020 mm

Type of wiring: a gold plated copper wiring (FIG. 5), a line width (wiring width) L (FIG. 4): 23 μm (an average value of 10 values measured by the microscope), a space width (wiring interval) S (FIG. 4): 27 μm (an average value of 10 values measured by the microscope), a wiring height: 12 μm

### Comparative Example 3

An anisotropic conductive film was produced, and then a joined structure was produced in the same manner as in Comparative Example 2, except that Ni—Au plated resin particles having an average particle diameter of 5 μm were used instead of the Ni—Au plated resin particles having an average particle diameter of 10 μm as the conductive particles in the production of the anisotropic conductive film of Comparative Example 2. The anisotropic conductive film produced in Comparative Example 3 was defined as ACF2.

TABLE 1

| | Ex. 1 | | Comp. Ex. 1 | | Comp. Ex. 2 | | Comp. Ex. 3 | |
|---|---|---|---|---|---|---|---|---|
| Substrate | FPC A | | | | FPC B | | | |
| Anisotropic conductive film | ACF1 | | ACF2 | | ACF1 | | ACF2 | |
| Pressure upon | 1 MPa | 3 MPa | 1 MPa | 3 MPa | 1 MPa | 3 MPa | 1 MPa | 3 MPa |
| pressure-bonding | | | | | | | | |
| Conductive resistance (Ω) | 2.0 | 1.9 | 8.4 | 2.0 | 2.0 | 1.8 | 8.6 | 1.9 |
| Short circuit (number) | 0 | 0 | 0 | 0 | 5 | 7 | 0 | 0 |

From Table 1, in Example 1, the average particle diameter of the conductive particles (10 μm) was larger than the line width (wiring width) L of the FPC substrate A (8 μm), thus it was considered that the conductive particles protruded from both edges of the wiring in a width direction by pressure-bonding the conductive particles with the wiring in the FPC substrate A. Moreover, the space width (wiring interval) S (42 μm) was 4.2 times larger (i.e., 3.5 times or more larger) than the average particle diameter of the conductive particles (10 μm). Thus, it was found that, even when the FPC substrate A and the ITO glass were joined at low pressure (1 MPa), the particles were sufficiently crushed so as to obtain excellent conductive reliability (conductive resistance of 2.0Ω) and to suppress the occurrence of short circuit between circuits (the number of occurrence of short circuit was 0).

On the other hand, in Comparative Example 1, the average particle diameter of the conductive particles (5 μm) was smaller than the line width (wiring width) L of the FPC substrate A (8 μm), thus it was found that the particles were not sufficiently crushed, even when the FPC substrate A and the ITO glass were joined at low pressure (1 MPa) so as not to obtain excellent conductive reliability (conductive resistance of 8.4Ω).

In Comparative Example 2, the average particle diameter of the conductive particles (10 μm) was 2.7 times larger (i.e., less than 3.5 times) than the space width (wiring interval) S of the FPC substrate B (27 μm). Thus, it was understood that short circuit between circuits occurred, wherein the number of the occurrence of the short circuit was 5 at 1 MPa, and 7 at 3 MPa.

In Comparative Example 3, the average particle diameter of the conductive particles (5 μm) was smaller than the line width (wiring width) L of the FPC substrate B (23 μm), thus it was found that the particles were not sufficiently crushed, when the FPC substrate B and the ITO glass were joined at low pressure (1 MPa), and that excellent conductive reliability (conductive resistance of 8.6Ω) could not be obtained.

The joined structure of the present invention can attain the sufficiently crushed state of particles, so that excellent conductive reliability can be obtained and occurrence of short circuit can be suppressed, even when the fine-pitch substrate and the electronic part or the like are joined.

The method for producing a joined structure of the present invention can efficiently produce the joined structure.

The anisotropic conductive film of the present invention can be suitably used to join various electronic parts and the substrate, or to join substrates, for example, suitably used to produce IC tags, IC cards, memory cards, flat panel displays or the like.

What is claimed is:

1. A joined structure comprising:
a first substrate having a wiring thereon;
any one of a second substrate and an electronic part; and
an anisotropic conductive film containing conductive particles,
wherein the first substrate and any one of the second substrate and the electronic part are electrically joined via the anisotropic conductive film, and
wherein the conductive particles pressure-bonded to the wiring of the first substrate protrude from both edges of the wiring in a width direction, and an interval of the wiring is 3.5 times or more larger than an average particle diameter of the conductive particles which are not pressure-bonded to the wiring.

2. A joined structure comprising:
a first substrate having a wiring thereon;
any one of a second substrate and an electronic part; and
an anisotropic conductive film containing conductive particles,
wherein the first substrate and any one of the second substrate and the electronic part are electrically joined via the anisotropic conductive film, and
wherein an average particle diameter of the conductive particles which are not pressure-bonded to the wiring of the first substrate is larger than a width of the wiring, and an interval of the wiring is 3.5 times or more larger than the average particle diameter of the conductive particles which are not pressure-bonded to the wiring.

3. The joined structure according to claim 1, wherein the anisotropic conductive film contains a binder resin and the binder resin contains at least one selected from an epoxy resin and an acrylic resin.

4. The joined structure according to claim 2, wherein the anisotropic conductive film contains a binder resin and the binder resin contains at least one selected from an epoxy resin and an acrylic resin.

5. A method for producing a joined structure, comprising:
forming an anisotropic conductive film on a surface to be processed; and
joining a first substrate and any one of a second substrate and an electronic part via the anisotropic conductive film,
wherein the joined structure comprises:
the first substrate having a wiring thereon;
any one of the second substrate and the electronic part; and
the anisotropic conductive film containing conductive particles,
wherein the first substrate and any one of the second substrate and the electronic part are electrically joined via the anisotropic conductive film, and
wherein the conductive particles pressure-bonded to the wiring of the first substrate protrude from both edges of the wiring in a width direction, and an interval of the wiring is 3.5 times or more larger than an average particle diameter of conductive particles which are not pressure-bonded to the wiring.

6. An anisotropic conductive film, comprising:
conductive particles,
wherein the anisotropic conductive film is used for a joined structure, which comprises:
a first substrate having a wiring thereon;
any one of a second substrate and an electronic part; and
the anisotropic conductive film containing the conductive particles,
wherein the first substrate and any one of the second substrate and the electronic part are electrically joined via the anisotropic conductive film, and
wherein the conductive particles pressure-bonded to the wiring of the first substrate protrudes from both edges of the wiring in a width direction, and an interval of the wiring is 3.5 times or more larger than an average particle diameter of the conductive particles which are not pressure-bonded to the wiring.
